(19) United States
(12) Patent Application Publication
(10) Pub. No.: US 2018/0061763 A1
(43) Pub. Date: Mar. 1, 2018

(54) DEVICE PERFORMANCE IMPROVEMENT USING BACKSIDE METALLIZATION IN A LAYER TRANSFER PROCESS

(71) Applicant: Qualcomm Switch Corp., San Diego, CA (US)

(72) Inventor: Sinan GOKTEPELI, San Diego, CA (US)

(21) Appl. No.: 15/246,453

(22) Filed: Aug. 24, 2016

(51) Int. Cl. H01L 23/535; H01L 29/78; H01L 29/06; H01L 29/45; H01L 27/12; H03K 17/687

(52) U.S. Cl. CPC H01L 23/535; H01L 29/785; H01L 29/0649; H03K 17/687; H01L 29/456; H01L 27/1211; H01L 29/78

(57) ABSTRACT

A silicon-on-insulator (SOI) device includes an active layer including active, devices, such as transistors. Below the active layer is an insulating layer, e.g., an SOI buried oxide layer (BOX), and below the BOX layer, one or more metal layers. The metal layer adjacent the BOX layer includes at least one metal region positioned below a corresponding active device, e.g., the channel region or diffusion region of the transistor. The metal region, during operation of the device, may act as a heat sink for the active device or may be biased to improve the performance of the active device.

### TECHNICAL FIELD

The present invention relates to silicon-on-insulator (SOI) technology, and more particularly to SOI devices with backside metallization.

### BACKGROUND

Silicon-on-insulator (SOI) devices use a layered silicon-insulator-silicon substrate structure as opposed to the more conventional bulk silicon substrate typically used in semiconductor manufacturing. In general, an SOI device consists of a semiconductor substrate on which a thin insulating layer, usually made of silicon dioxide and referred to as the “buried oxide” or “BOX,” layer is formed, e.g., by implantation of oxygen into the bulk silicon substrate. An active region of silicon is formed on the BOX layer. The active silicon layer includes circuit elements of an integrated circuit (IC), e.g., transistors and diodes.

One advantage of isolating the circuitry of the active layer from the bulk semiconductor substrate using the buried oxide layer is a decrease in parasitic capacitance, which improves performance, e.g., provides increased device speed and reduced power usage. Because of these advantages, SOI structures are desirable for high frequency applications such as radio frequency (RF) communication circuits.

A conventional SOI structure 100 is shown in FIG. 1. The SOI structure 100 includes a substrate layer 101, an insulator layer (BOX) 102, and an active layer 103. The substrate layer 101 is typically a semiconductor material such as silicon. The insulator layer 102 is a dielectric which is often silicon dioxide formed through the oxidation of a portion of the substrate layer 101 where the substrate layer is silicon. The active layer 103 includes an active device layer 104 and a metallization or metal interconnect layer 105. The active layer 103 further includes a combination of dopants, dielectrics, polysilicon, metal wiring, passivation, and other layers, materials or components that are present after circuitry has been formed therein. The circuitry may include metal wiring 106 (e.g. in the metal interconnect layer 105), passive devices such as resistors, capacitors, and inductors, and active devices such as a transistor 107 (e.g., in the active device layer 104).

One issue that may arise with SOI devices is relatively high leakage in the devices of the active layer. In order to compensate for such leakage, a higher threshold voltage (Vt) may be necessary. However, a high Vt may limit the devices' performance and speed.

Another potential issue with SOI devices is high thermal resistance. High thermal resistance materials take longer to disperse heat compared to lower thermal resistance materials, thereby preventing an active device, such as a transistor, from cooling down. Self-heating may occur when operation of the active device causes increases in temperature in the device which cannot be adequately dissipated. As temperature increases in the device, electron mobility decreases, causing the drain current to drop.

FIG. 2 is a plot illustrating the effects of thermal resistance on the drain current (Id) of an SOI device. Plotted line 202 shows Id increasing with the drain voltage (Vd) and eventually stabilizing at Vd1 in the absence of increased temperature in the device. Plotted line 204 shows the effect of heating due to high thermal resistance on the same device. Such heating may result in up to 10% in Id degradation. Also, leakage current may increase exponentially with increased temperature in the device, further reducing performance.

Accordingly, there is a need in the art for silicon-on-insulator devices with improved thermal resistance and reduced leakage currents yet also having sufficient operating speed.

### SUMMARY

To provide improved thermal resistance and reduced leakage current without reducing operating speed, a silicon-on-insulator (SOI) device is produced through a layer transfer process to have an buried oxide layer with an exposed surface and a device-facing surface adjacent an semiconductor layer having transistor channel regions. A metal layer is deposited on the exposed surface so as to face the transistor channel regions. By biasing the metal layer, the threshold voltage for the transistors may be raised during inactive or sleep modes so as to greatly reduce leakage currents from the biased transistors. Conversely, the bias of the metal layer may be changed during an active mode of operation to lower the threshold voltage to increase the switching speeds of the transistors.

In addition, the metal layer functions as a heat sink to conduct heat from the transistors during their operation to prevent heat-induced reductions in drive currents for the transistors. The metal layer thus allows the SOI devices to dissipate heat more effectively and reduces negative effects such as decreased mobility and device performance that would otherwise occur during high-performance operation that generates abundant heat.

These and additional advantageous features for the disclosed silicon-on-insulator devices may be better appreciated through consideration of the following detailed description.

### BRIEF DESCRIPTION OF THE DRAWINGS

FIG. 1 is a cross-sectional view of a silicon-on-insulator (SOI) device.

FIG. 2 is a plot showing the effect of thermal resistance on saturation drain current in an SOI device as a function of the drain-to-source voltage.

FIG. 3 shows a device processed using a layer-transfer process.

FIG. 4 shows an SOI device processed using a layer-transfer process according to an embodiment.

FIG. 5 is a plot showing the effect of application of Vbias on the post-layer transfer metal on the active device.

FIG. 6a shows the effect on the drive current caused by self-heating in a transistor without a post-layer transfer metal beneath it.

FIG. 6b shows the effect of the addition of a post-layer transfer metal acting as a heat sink.

FIG. 6c shows the effect of the addition of a post-layer transfer metal while correctly biased and acting as a heat sink.

Embodiments of the disclosed SOI devices and their advantages are best understood by referring to the detailed description that follows. It should be appreciated that like reference numerals are used to identify like elements illustrated in one or more of the figures.

### DETAILED DESCRIPTION

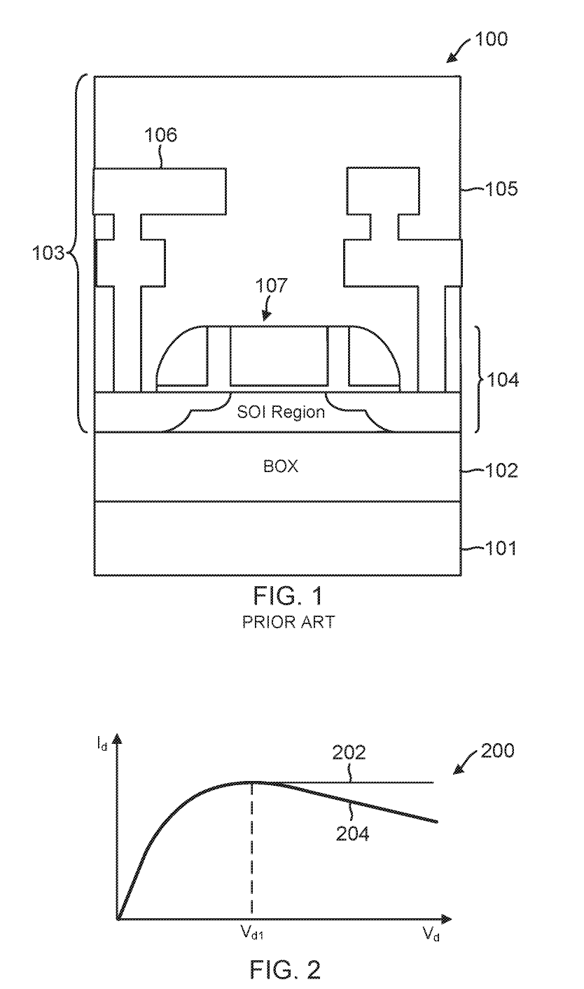

In a layer transfer process for a silicon-on-insulator (SOI) device such as structure 100 of FIG. 1, the active layer is bonded to a handle substrate so that the original substrate may be removed. For example, the substrate may be ground away using a chemical-mechanical polishing step or removed by etching. The buried-oxide (BOX) layer may also be thinned through a polishing step to finish a conventional layer transfer process. Such a layer transfer process is advantageous as it reduces parasitic coupling (e.g., parasitic capacitive coupling) that would otherwise occur between the active devices and metal layers within the active layer and the original substrate. This conventional layer transfer process for an SOI device is modified herein to include a deposition of a backside metal layer on the exposed surface of the BOX layer. Unlike conventional backside metallizations to provide vias and leads, the backside metal layer disclosed herein is positioned to face the channels of the active devices within the active layer.

Because the backside metal layer is adjacent the active device channels, it functions as a heat sink and inhibits heat-induced weakening of the drive currents for the active devices during high-speed operation. In addition, the proximity of the backside metal layer to the active device channels enables a biasing of the backside metal layer to adjust the threshold voltages for the active devices. By adjusting the amplitude and polarity of the bias voltage applied to the backside metal layer, a power mode control circuit may control whether the active devices operate with a relatively high threshold voltage or a relatively-low threshold voltage. In general, leakage currents have an inversely exponential relationship to the threshold voltage. If the threshold voltage for a transistor is increased, its leakage current is thus reduced dramatically. Although it would thus be desirable to dope the SOI transistor to have a relatively-high threshold voltage, such elevated threshold voltages reduce the device operating speed during normal or active operation. There has thus been an unsolved tension between maintaining a high threshold voltage to reduce leakage currents while providing a sufficient operating speed.

The reduction of leakage currents in mobile device is particularly desirable since a dormant mode is typically the predominate mode of operation for such devices. Eliminating or reducing leakage currents during dormant modes of operation for a mobile device is thus critical in extending battery life. But a permanent increase in threshold voltage would lead to user dissatisfaction despite the increased battery life due to undesirably slow operation during active modes of operation such as web browsing or video gaming. The biasing of the backside metal layer disclosed herein advantageously solves the tension between requiring a high threshold voltage to reduce leakage current yet also requiring a low threshold voltage for high-speed operation. For example, the backside metal layer may be biased with a positive voltage such as 5.0 V that can then be adjusted down to a negative voltage such as −5.0 V to shift the threshold voltage by approximately 1.5 V. Since the leakage current is inversely proportional to an exponential function of the threshold voltage, such an increase in threshold voltage dramatically lowers the leakage currents during a dormant or sleep mode of operation. Yet the threshold voltage can then be reduced to provide equally dramatic speed increases during a high-speed or active mode of operation. Moreover, the backside metal layer functions as a heat sink for the heat produced during high-speed operation to lower or eliminate heat-induced reductions in the transistor drive currents. Such heat-induced effects are particularly problematic in conventional SOI devices since the BOX layer functions as a thermal insulator. The backside metal layer disclosed herein alleviates this thermal insulation. Some example embodiments will now be discussed to further illustrate these advantageous features.

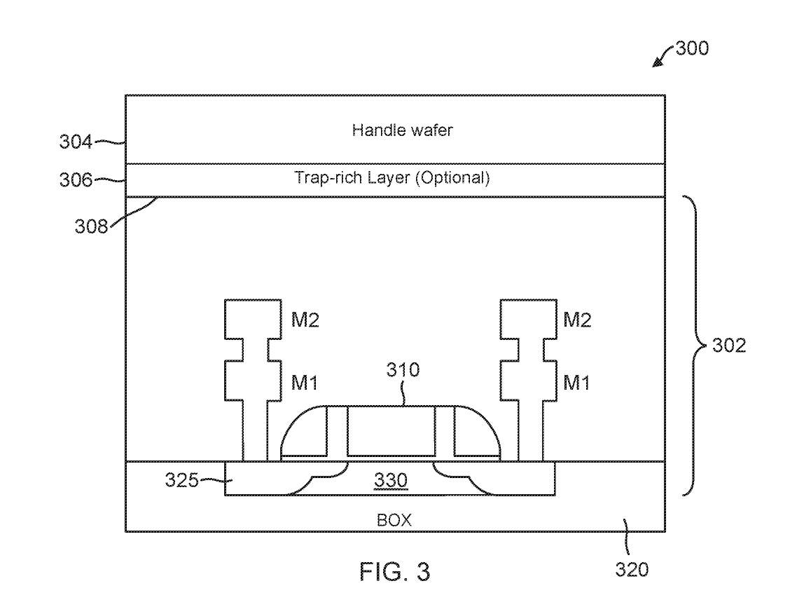

FIG. 3 shows an SOT device 300 produced using a layer-transfer process prior to the deposition of the backside metal layer. An active layer includes active devices such as a transistor (for illustration clarity, only one transistor is shown but it will be appreciated that active layer will contain many such transistors). Transistor is formed in a silicon layer that abuts a buried oxide (BOX) layer with an exposed surface. This exposed surface formerly abutted or faced a semiconductor substrate (e.g. substrate 101 of FIG. 1) that has been removed as is conventional in a layer transfer process for an SOI device. Prior to the removal of the substrate, a handle wafer (which may also be denoted as a handle substrate) 304 is bonded to an upper surface of active layer 302 through a bonding layer (not illustrated). Such a bonding layer may comprise an insulator or passivation layer that is deposited through a physical vapor deposition process. Alternatively, the bonding layer may be an oxide layer created through a chemical or thermal oxidation process. In SOI device 300, handle wafer 304 comprises silicon but it may comprise any suitable substrate such as silicon germanium.

As compared to substrate 101, handle wafer 304 is further displaced from a channel region 330 for transistor 310. In addition, handle wafer 304 is further displaced from the various metal layers within active layer 302 such as metal layers M1 and M2 and associated vias. These metal layers and vias allow signals, power, and ground to be applied to the active devices such as transistor 310. Since these structures are conducting, they will tend to induce an undesirable capacitive coupling with a substrate such as substrate 101 or handle wafer 304. But the relative displacement of handle wafer from these conducting structures significantly reduces this parasitic coupling as compared to conventional SOI device 100. To further reduce the parasitic coupling, handle wafer 304 may include a trap-rich layer 306. For example, the crystal lattice within trap-rich layer 306 may be disrupted through irradiation or through an implantation of a suitable implant such as Si, C, or Ar. The disruption to the crystal lattice causes the formation of electrically-active carrier traps, which significantly reduces parasitic coupling to handle wafer 304. In particular, the junction between silicon wafer 304 and active layer 302 typically results in the formation of free carriers along an active-layer-facing surface 308 of silicon wafer 304. These free carriers then undesirably parasitically couple with the conducting structures in active layer 302. But the carrier traps in trap-rich layer 306 capture these free carriers to inhibit this coupling, leading to a substantial reduction of radio frequency (RF) losses and crosstalk.

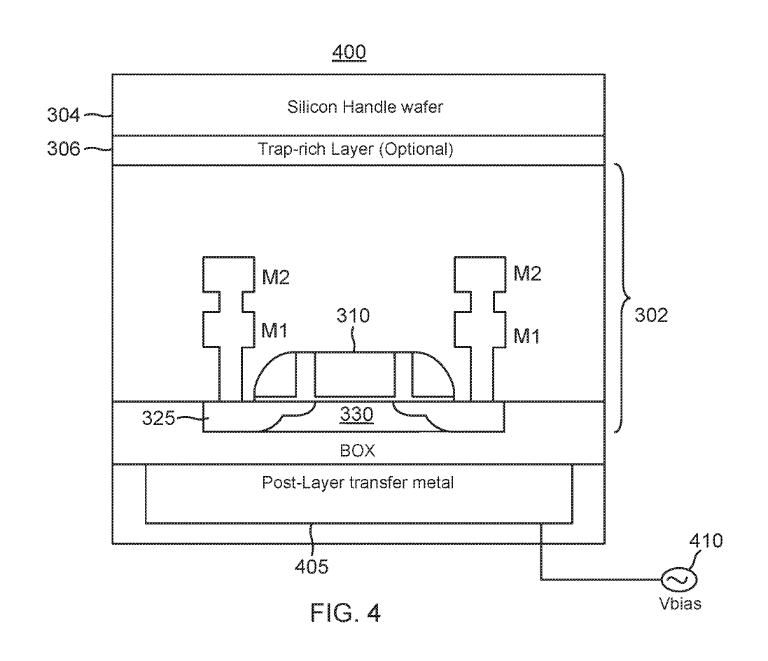

After the formation of initial SOI device 300, a backside metal layer 405 may then be deposited to form a completed SOI device 400 as shown in FIG. 4. Since backside metal layer 405 is applied after the transfer layer process, it may also be denoted as a post-layer-transfer-process metal layer. Such metallization directly below channel region 330 is typically avoided due to uncertainty regarding its effect on the device operation. But this effect on operation is exploited as discussed herein to substantially reduce leakage current and reduce heat-induced reductions in device performance. Backside metal layer 405 may be deposited using conventional techniques such as atomic layer deposition, electroplating, or physical vapor deposition and patterned using photolithography. Backside metal layer 405 may comprise copper, aluminum, or alloys of either metal, however a variety of other metals may also be substituted. Backside metal layer faces channel region 330 of transistor 310 and may also face the entire diffusion region on which such transistors are formed. Transistor 310 may comprise a standard planar architecture or may be three-dimensional such as in a fin-shaped field effect transistor (FinFET) or nanowire device.

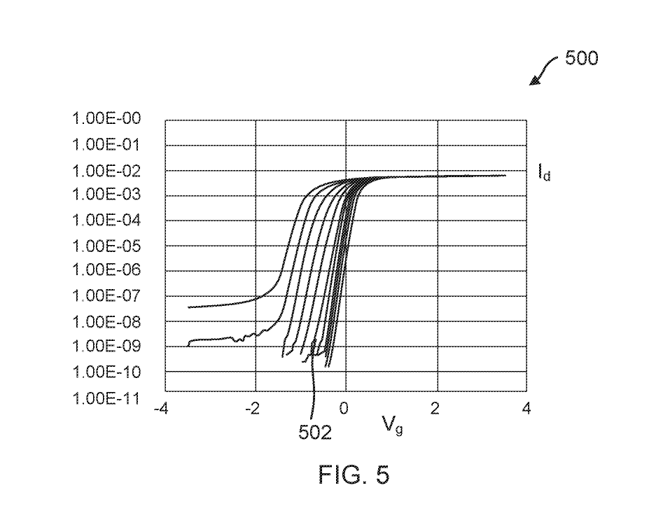

A power mode control circuit 410 controls a bias voltage applied to backside metal layer 405 to control the threshold voltage (Vt) for active devices such as transistor 310. Depending upon whether a circuit such as a processor including transistor 310 operates in a sleep mode or in an active mode of operation, power mode control circuit 410 adjusts the threshold voltage of transistor 310 accordingly. By changing the bias on backside metal layer 405, the threshold voltage may be shifted by approximately a 1.5V range. At the low end of this threshold voltage range, transistor 310 has higher leakage current but greater switching speed. At the high end of the threshold voltage range, transistor 310 has lower switching speed but greatly reduced leakage currents. For example, such biasing of backside metal layer 405 can provide a leakage current reduction of more than 3 decades as shown in a plot 500 of FIG. 5. The plotted line 502 represents 0 Vbias. The lines to the left of plotted line 502 represent the application of an increasingly positive Vbias, and the lines to the right of 502 represent the application of an increasingly negative Vbias. The y axis represents the drain current (Id) whereas the x axis is the gate voltage. In one embodiment, power mode control circuit 410 may be deemed to comprise a means for biasing backside metal layer 405.

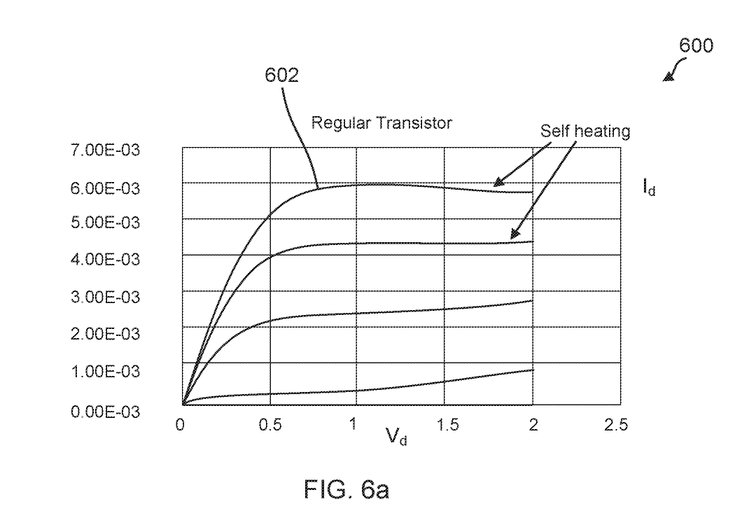

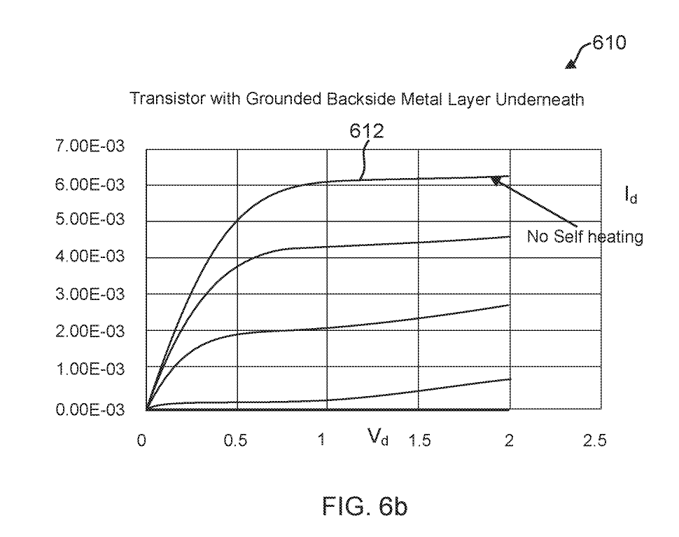

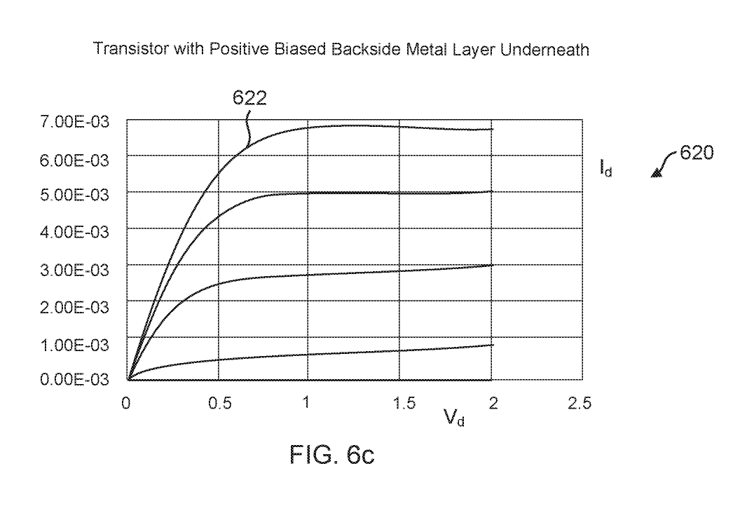

The effect of backside metal layer 405 in reducing the self-heating reduction of the drive current may be better appreciated through a comparison of FIG. 6a and FIG. 6b. FIG. 6a is a graph 600 showing the effect on the drive current (Id) caused by self-heating for a conventional SOI device such as SOI device 100 of FIG. 1. The y-axis is the drive current Id whereas the x-axis is the drain-to-source voltage. A plurality of plotted lines 602 correspond to different gate voltages, starting from a zero gate voltage and increasing as the drive current increases. At higher values of the source-to-drain voltage (e.g., greater than 1 volt), the drive current decreases for the plotted lines 602 corresponding to higher gate voltages. In contrast, FIG. 6b is a graph 610 showing the effect of the addition of a backside metal layer on the drive current 612. As with FIG. 6a, various drive currents 612 are shown corresponding to various gate voltages. The higher gate voltages produce the stronger drive currents. The x-axis and y-axis parameters are the same as discussed with regard to FIG. 6a. Note that drive currents 612 advantageously do not have self-heating reductions even as the drain-to-source voltage is increased above 1 V. The backside metal layer acts as a heat sink and mitigates the self-heating effects. This may improve the drive current by nearly 5% as opposed to conventional operation. FIG. 6c is a graph 620 for drive currents 622 in which the backside metal layer is biased to provide yet another 5-7% improvement in the drive current as compared to FIG. 6a.

Although different embodiments have been discussed primarily with respect to specific embodiments thereof, other variations are possible. Various configurations of the described system may be used in place of, or in addition to, the configurations presented herein. For example, the metal region layer does not need to be applied device by device. They can be placed separately underneath the n-type field effect transistors (nFETs) of a circuit block and the p-type field effect transistors (pFETs) of a circuit block. This may enable reduction of leakage and/or increase performance of circuit(s) in a product.

As another example, configurations were described with general reference to silicon substrates but other types of semiconductor material could be used in the place of silicon.

While the specification has been described in detail with respect to specific embodiments of the present invention, it will be appreciated that those skilled in the art, upon attaining an understanding of the foregoing, may readily conceive of alterations to, variations of, and equivalents to these embodiments. Additionally, a person having ordinary skill in the art will readily appreciate that the terms “upper” and “lower” are sometimes used for ease of describing the figures, and indicate relative positions corresponding to the orientation of the figure on a properly oriented page, and may not reflect the proper orientation of an SOI device as implemented. These and other modifications and variations to the present invention may be practiced by those skilled in the art, without departing from the scope of the present disclosure, which is more particularly set forth in the appended claims.

We claim:

1. A silicon-on-insulator (SOI) device comprising:
an active layer including a transistor;
a handle substrate above the active layer;
an insulator layer below the active layer, the insulator layer having an active layer surface facing the active layer and an opposing surface facing away from the active layer; and
a backside metal layer on the opposing surface of the insulator layer and positioned directly below the transistor.

2. The SOI device of claim 1, wherein the transistor is a planar transistor.

3. The SOI device of claim 1, wherein the transistor is a fin-shaped field effect transistor (FinFET).

4. The SOI device of claim 1, wherein the insulator layer comprises a silicon dioxide buried oxide layer.

5. The SOI device of claim 1, further comprising a voltage source configured to bias the backside metal layer with a bias voltage.

6. The SOI device of claim 5, wherein the voltage source comprises a power mode control circuit configured to adjust the bias voltage responsive to an operating mode for a circuit including the transistor.

7. The SOI device of claim 6, wherein the circuit is configured to operate in a sleep mode of operation and in an active mode of operation, and wherein the power mode control circuit is further configured to bias the backside metal layer during the sleep mode of operation so as to increase a threshold voltage for the transistor and to bias the backside metal layer during the active mode of operation so as to decrease the threshold voltage for the transistor.

8. The SOI device of claim 1, wherein the active layer comprises a plurality of transistors in a contiguous region of the SOI device, and wherein the backside metal layer is positioned below said contiguous region.

9. The SOI device of claim 1, further comprising a trap-rich layer between the active layer and the handle substrate.

10. The SOI device of claim 1, wherein the handle substrate comprises silicon, and wherein the backside metal layer comprises aluminum.

11. A method of operation for an SOI device, the method comprising:
during a sleep mode for a circuit including a transistor in an active layer between a handle substrate and a buried oxide layer, increasing a threshold voltage for the transistor by biasing a backside metal layer adjacent the buried oxide layer with a first voltage; and
during an active mode of operation for the transistor, biasing the backside metal layer with a second voltage to reduce the threshold voltage for the transistor.

12. The method of claim 11, further comprising conducting heat from the transistor during the active mode through the backside metal layer.

13. The method of claim 11, wherein the first voltage is a negative voltage and the second voltage is a positive voltage.

14. The method of claim 11, further comprising isolating the handle substrate from the transistor by trapping free carriers in a trap-rich layer between the handle substrate and the active layer.

15. The method of claim 11, wherein said biasing the backside metal layer further comprises biasing a channel region of the transistor.

16. A silicon-on-insulator (SOI) device comprising:
an active layer comprising an active device;
a substrate above the active layer;
an insulator layer below the active layer;
a backside metal layer below the insulator layer and positioned directly below at least a portion of the active device; and
means for biasing the backside metal layer.

17. The SOI device of claim 16, wherein the means for biasing the backside metal layer comprises a voltage source electrically connected to the backside metal layer.

18. The SOI device of claim 16, wherein the active device comprises a transistor including a channel region, and
wherein the backside metal layer is positioned below the channel region.

19. The SOI device of claim 16, wherein the active device comprises a transistor including a diffusion region, and
wherein the backside metal layer is positioned below the diffusion region.

20. The SOI device of claim 16, further comprising:
a trap-rich layer for capturing free carriers between the active layer and the substrate.
